(19) United States
(12) Patent Application Publication
(10) Pub. No.: US 2006/0105250 A1
(43) Pub. Date: May 18, 2006

(54) Test photomask and compensation method using the same

(75) Inventor: Shih-Hsuan Liu, Taoyuan City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Allied Material Technology Corporation

(21) Appl. No.: 11/114,448

(22) Filed: Apr. 26, 2005

(30) Foreign Application Priority Data
Nov. 18, 2004 (TW) 093135498

(51) Int. Cl. G03C 5/00; G03F 9/00; G03F 1/00

(52) U.S. Cl. 430/5; 430/30; 430/22

(57) ABSTRACT

A test photomask and a compensation method using the same are disclosed. The present invention employs several groups of parallel lines in the longitudinal direction and in the traverse direction on the test photomask to fabricate the test photomask. The parallel lines have different widths thereof and widths of pitches. Then, the differences of widths of these parallel lines and the difference of widths of pitches are determined so that widths of these parallel lines and pitches of the patterns are compensated.

### BACKGROUND OF THE INVENTION

1. Field of the Invention

The present invention relates to a photomask and a compensation method using the same, and in particular to a test photomask and a compensation method during the lithography process.

2. Description of Related Art

Generally speaking, requirement of resolution for color filters of liquid crystal displays is not so demanding (more than 6 μm) as that of integrated chips fabrication. Then, to increase production, a proximity-field exposure method is employed in the lithography process. However, the proximity-field exposure method uses a 1:1 photomask. That is, the size of pattern area of the photomask is the same as that of glass substrate. With increase of the size of the glass substrate, the size of the photomask must be increased so that cost goes up. For example, dimension of the photomask for G5 factory is 1100 mm×700 mm, and each photomask is worth about NT 7.5 millions dollars.

During the lithography process, because of property of photoresist and parallelism of light beams of an exposure device, patterns of the photomask and do not match with those transferred to the photoresist. Thus, the above disadvantage should be taken into account when preparing for the photomask.

Photoresists can be either positive-acting photoresist or negative-acting photoresist. For a positive-acting photoresist, exposed portions of the photoresist are rendered more soluble in a developer solution and the exposed portions thereof are removed. The pattern on the photoresist is the same as that of the photomask. For negative-acting photoresists, the exposed portions are rendered less soluble in the developer solution than the unexposed portions because of crosslink in a reaction between a photoactive compound and polymerizable reagents. Contrary to the positive-acting photoresist, the unexposed portions thereof are removed. The pattern on the photoresist is complementary to that of the photomask.

Because of the diffraction and a distance between the photomask and the glass substrate, a trapezoidal configuration of the distribution of the exposure energy on the glass substrate is shown in FIG. 1. Referring to FIG. 1, light beams 160 are transmitted through a transparent portion 150 of a photomask 110 so that a portion of a photoresist layer 100 is exposed. Thus, it results in a trapezoidal exposed portion 120 and an unexposed portion 130. If the photoresist layer 100 is the positive-acting photoresist layer, then the exposed portion 120 of the photoresist layer 100 is removed and the unexpected portion 130 remains intact. In addition, if the photoresist layer 100 is the negative-acting photoresist layer, then the exposed portion 120 of the photoresist layer 100 remains intact and the unexpected portion 130 is removed.

As also shown in FIG. 1, the transparent portion 150 of the photomask 110 has a linewidth of W1, and an opaque portion 140 of the photomask 110 has a linewidth of W2. Besides, the backside of the exposed portion 120 of the photoresist layer 100 has a linewidth of Wn, and a backside of the photoresist layer 100 under the opaque portion 140 of the photomask 110 has a linewidth of Wp. Because a difference between the linewidth of the exposed portion 120 and the unexposed portion 130 exists, it results in a linewidth variation. Thus, the difference must be compensated during the process of photomask fabrication.

Further referring to FIG. 1, the linewidth Wn of the exposed portion 120 of the photoresist layer 100 is longer than the linewidth W1 of the transparent portion 150 of the photomask 110. In this regard, the linewidth W1 of the photomask 110 should be decreased (Wn−W1=Wnc) to compensate the difference during the process of photomask fabrication. Similarly, the linewidth Wp of the unexposed portion 130 is shorter than the linewidth W2 of the opaque 140 of the photomask 110. In this regard, the linewidth W2 of photomask 110 should be increased (W2−Wp=Wpc) to compensate the difference during the process of photomask fabrication.

Thus, there is need to development for method to determine parameters of test photomasks and save cost of manufacturing test photomasks.

### SUMMARY OF THE INVENTION

It is an object of the present invention to provide a test photomask. The present invention is used to determine parameters of the test photomasks in more efficient way.

It is another object of the present invention to provide a method for compensating patterns of the test photomask to determine parameters of the test photomasks in more efficient way.

In order to accomplish the object of the present invention, the present invention provides provide a test photomask. The test photomask includes at least four patterns. The first pattern includes a group of first parallel lines and neighboring first parallel lines are separated by first pitches in the traverse direction. Each of the first pitches is uniform. The second pattern includes a group of second parallel lines and neighboring second parallel lines are separated by second pitches in the traverse direction. Width of each second parallel line is uniform. The third pattern includes a group of third parallel lines and neighboring third parallel lines are separated by third pitches in the longitudinal direction. Each of the third pitches is uniform. The fourth pattern includes a group of fourth parallel lines and neighboring fourth parallel lines are separated by fourth pitches in the traverse direction. Width of each fourth parallel line is uniform.

In accordance with the present invention, width of the first parallel lines is different from that of the third parallel lines, and the difference between them is in the range of 0-300 μm. Besides, width of the first pitches is different from that of the third pitches, and the difference between them is in the range of 0-300 μm.

In order to accomplish the object of the present invention, the present invention provides a method for compensating the patterns of the test photomask. The method comprises the following steps. Firstly, a photoresist layer is deposited on a surface of a substrate, and a test photomask is positioned above the glass substrate. The exposure process is performed on the glass substrate through light beams. The test photomask includes at least four patterns. The first pattern includes a group of first parallel lines and neighboring first parallel lines are separated by first pitches in the traverse direction. Each of the first pitches is uniform. The second pattern includes a group of second parallel lines and neighboring second parallel lines are separated by second pitches in the traverse direction. Width of each second parallel line is uniform. The third pattern includes a group of third parallel lines and neighboring third parallel lines are separated by third pitches in the longitudinal direction. Each of the third pitches is uniform. Following exposure, the development process is performed on the deposited photoresist. Comparing the patterns of the test photomask with those transferred to the photoresist, the differences of the widths of the parallel lines and differences of the pitches are determined. Pursuant to these differences, widths and pitches of these parallel lines are compensated.

In accordance with one embodiment of the present invention, width of the first parallel lines is different from that of the third parallel lines, and the difference between them is in the range of 0-300 μm. Besides, width of the first pitches is different from that of the third pitches, and the difference between them is in the range of 0-300 μm.

### BRIEF DESCRIPTION OF THE DRAWINGS

The present invention can be fully understood from the following detailed description and preferred embodiment with reference to the accompanying drawings, in which:

FIG. 1 shows a trapezoidal configuration of the distribution of the exposure energy on the glass substrate; and

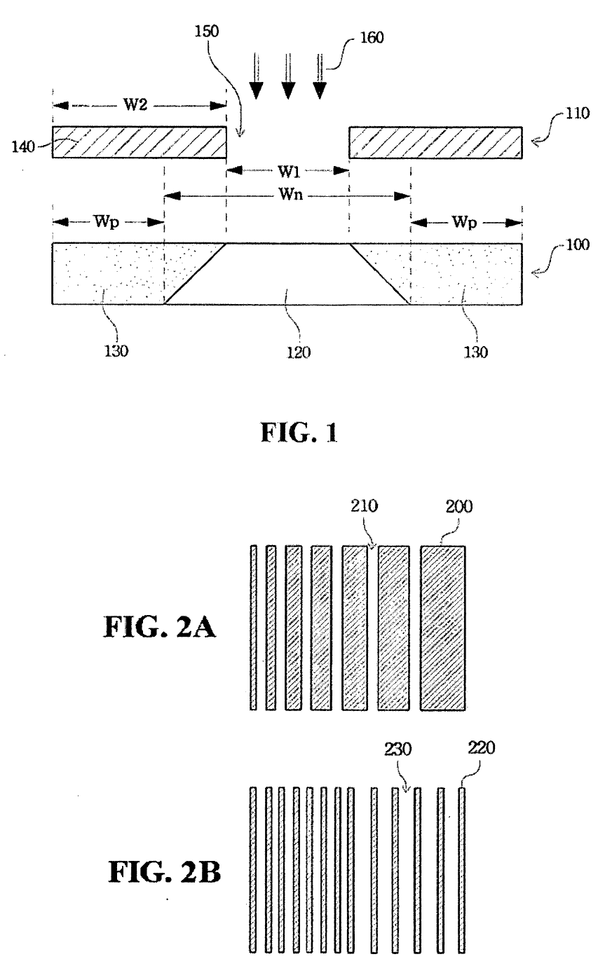

FIGS. 2A-2D illustrates test patterns of the test photomasks according to one embodiment of the present invention.

### DETAILED DESCRIPTION OF THE PREFERRED EMBODIMENTS

The following detailed description is of the best presently contemplated modes of carrying out the invention. This description is not to be taken in a limiting sense, but is made merely for the purpose of illustrating general principles of embodiments of the invention. The scope of the invention is best defined by the appended claims.

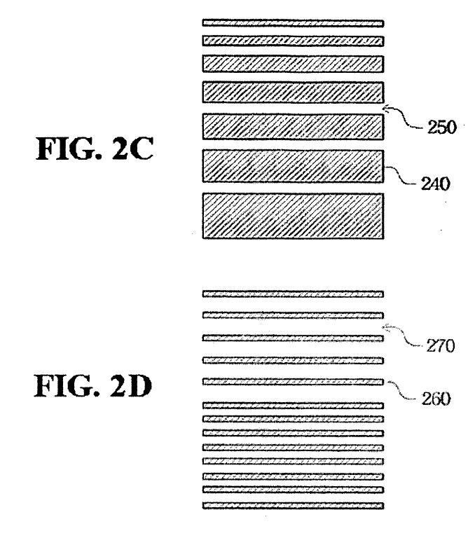

Reference is made to FIGS. 2A-2D. FIGS. 2A-2D illustrate test patterns of test photomasks of the present invention. Referring to FIG. 2A, width of each of first parallel lines 200 is not necessarily uniform, and however, width of each of first pitches 210 of neighboring first parallel lines 200 is uniform. Widths of the first parallel lines 200 and the first pitches 210 can be adjusted so as to conform to the requirement of product. For example, according to the present invention, the width of each of the first parallel lines 200 is preferably in the range of 0-300 μm. Besides, the width of each of the first pitches 210 is preferably in the range of 0-300 μm.

Reference is made to FIG. 2B. FIG. 2B illustrates a group of second parallel lines 220. The width of each of the second parallel line 220 is uniform. Pitches 230 between neighboring second parallel lines 220 are not necessarily uniform. The widths of the second parallel lines 220 and pitches 230 between neighboring second parallel lines 220 may vary so as to conform to the requirement of product. For example, according to the present invention, the width of each of second parallel lines 220 is preferably in the range of 0-300 μm. Besides, the width of each of the second pitches 230 is preferably in the range of 0-300 μm.

Reference is made to FIGS. 2C and 2D. FIG. 2C illustrates a group of third parallel lines 240. Likely the first parallel lines 200, width of each of the third parallel line 240 is not necessarily uniform, and pitches 250 between neighboring third parallel lines 240 are uniform. FIG. 2D illustrates a group of fourth parallel lines 260. Likely the second parallel lines 220, width of each of the fourth parallel line 260 is uniform, and pitches 270 between neighboring fourth parallel lines 260 are not necessarily uniform.

Furthermore, the above-mentioned parallel lines are fabricated on the test photomask. For example, the test photomask includes nine rectangular areas. The above-mentioned parallel lines are fabricated on each rectangular area of the test photomask. Then, a photoresist layer is deposited on the surface of the test photomask. Following this step, lithography process is performed on the patterns of the test photomask. After the lithography process is completed, the pattern of the photomask is compared with the widths of the parallel lines and widths of the pitches of neighboring parallel lines of the photoresist layer. The difference between them is determined so that the difference can be compensated.

The advantage of the present invention is provided below. Because there are test patterns with different widths of the pitches and different widths of the parallel lines, the difference between them can be determined and compensated simultaneously no matter what widths of the pitches and the parallel lines are. Thus, according to the embodiment of the present invention, parameters of design of test photomasks is obtained in more efficient way so that cost of fabrication of test photomask is saved.

While the invention has been described with reference to the preferred embodiments, the description is not intended to be construed in a limiting sense. It is therefore contemplated that the appended claims will cover any such modifications or embodiments as may fall within the scope of the invention defined by the following claims and their equivalents.

What is claimed is:

1. A test photomask, comprising:
a group of first parallel lines, separated by first pitches and each of the first pitches being uniform;
a group of second parallel lines, separated by second pitches and width of each second parallel line being uniform;
a group of third parallel lines, separated by third pitches and each of the third pitches being uniform; and
a group of fourth parallel lines, separated by fourth pitches and width of each fourth parallel line being uniform.

2. The test photomask as claimed in claim 1, wherein a width of the first parallel lines is different from that of the third parallel lines, and the difference between them is in the range of 0-300 μm.

3. The test photomask as claimed in claim 1, wherein a width of the first pitches is different from that of the third pitches, and the difference between them is in the range of 0-300 μm.

4. A method for compensating patterns of a test photomask, comprising the step:
depositing a photoresist layer on a substrate;
exposing the photoresit layer and the test photomask to light beams, the patterns of the test photomask, comprising:
a group of first parallel lines, separated by first pitches and each of the first pitches being uniform;
a group of second parallel lines, separated by second pitches and width of each second parallel line being uniform;
a group of third parallel lines, separated by third pitches and each of the third pitches being uniform; and
a group of fourth parallel lines, separated by fourth pitches and width of each fourth parallel line being uniform;
performing a development process on the photoresist layer;
comparing the patterns of the test photomask with those transferred to the photoresist layer; and
determining the differences of widths of these parallel lines and the difference of widths of pitches so as to compensate for the widths of these parallel lines and pitches of the patterns.

5. The method as claimed in claim 4, wherein a width of the first pitches is different from that of the third pitches, and the difference between them is in the range of 0-300 μm.

6. The method as claimed in claim 4, wherein a width of the first pitches is different from that of the third pitches, and the difference between them is in the range of 0-300 μm.
